(19) United States
(12) Patent Application Publication
(10) Pub. No.: US 2026/0090151 A1
(43) Pub. Date: Mar. 26, 2026

(54) OPTOELECTRONIC DEVICE, MOLD FOR PRODUCING A MOLDED BODY FOR AN OPTOELECTRONIC DEVICE AND METHOD FOR PRODUCING AN OPTOELECTRONIC DEVICE

(71) Applicant: ams-OSRAM International GmbH, Regensburg (DE)

(72) Inventors: Guan Liang Lee, Bayan Lepas (MY); Joo Ding Ngu, Bayan Lepas (MY)

(21) Appl. No.: 19/109,972

(22) PCT Filed: Sep. 19, 2023
(86) PCT No.: PCT/EP2023/075758

§ 371 Date: Mar. 7, 2025

(30) Foreign Application Priority Data
Sep. 21, 2022 (DE) 10 2022 124 236.6

(51) Int. Cl. H10H 20/853; H10H 20/85; H10H 29/01; H10H 29/24; H10H 29/85; H10H 29/853

(52) U.S. Cl. CPC H10H 20/853; H10H 20/8508; H10H 29/034; H10H 29/0362; H10H 29/24; H10H 29/8508; H10H 29/853

(57) ABSTRACT

In at least one embodiment, an optoelectronic device includes a carrier with a mounting area, an optoelectronic semiconductor chip mounted at the mounting area of the carrier and a filling material arranged on the mounting area laterally next to the semiconductor chip, wherein a side surface of the semiconductor chip is wetted by the filling material. The optoelectronic device further comprises at least one attraction feature at the mounting area laterally next to and spaced from the semiconductor chip. The attraction feature is at least laterally surrounded by the filling material. The attraction feature is different from the portion of the mounting area, which lies laterally next to the attraction feature and which laterally surrounds the attraction feature. Further, the attraction feature is configured to attract a liquid phase of the filling material due to minimization of surface energy.

### CROSS-REFERENCE TO RELATED APPLICATIONS

This patent application is a national phase filing under section 371 of PCT/EP2023/075758, filed Sep. 19, 2023, which claims the priority of German patent application no. 102022124236.6, filed Sep. 21, 2022, each of which is incorporated herein by reference in its entirety.

### TECHNICAL FIELD

The disclosure relates to an optoelectronic device, to a mold for producing a molded body for an optoelectronic device and to a method for producing an optoelectronic device.

### SUMMARY

Embodiments provide an improved optoelectronic device, e.g. an optoelectronic device with good optical properties. Further embodiments provide a mold with which a molded body for such an optoelectronic device can be produced. Yet other embodiments provide a method for producing such an optoelectronic device.

First, the optoelectronic device is specified.

According to at least one embodiment, the optoelectronic device comprises a carrier with a mounting area. The mounting area may be flat. The mounting area is, for example, formed by a top side of the carrier.

The carrier comprises, for example, a lead frame embedded in a molded body so that the mounting area is partially formed by the lead frame and partially by the molded body. Alternatively, the carrier may be ceramic carrier or a PCB.

According to at least one embodiment, the optoelectronic device comprises an optoelectronic semiconductor chip mounted at or on the mounting area of the carrier.

The optoelectronic semiconductor chip may be electrically connected to the carrier. For this purpose, the mounting area of the carrier may comprise electrically conductive connection areas. For example, the semiconductor chip is soldered to the connection areas. The optoelectronic semiconductor chip is, for example, a flip-chip with all contact areas on a side of the chip facing the mounting area.

The optoelectronic semiconductor chip may be an LED chip or a laser chip.

Particularly, the optoelectronic semiconductor chip is configured to produce and emit electromagnetic radiation, for example in the visible spectral range or in the UV range or in the IR range. The optoelectronic semiconductor chip may be based on a II-V compound semiconductor material, like AlₙIn₁₋ₙ₋ₘGaₘN.

The optoelectronic device may comprise two or more optoelectronic semiconductor chips mounted on the mounting area. All features disclosed in connection with one optoelectronic semiconductor chip are also disclosed for the other optoelectronic semiconductor chips.

According to at least one embodiment, a filling material is arranged on the mounting area of the carrier laterally next to the semiconductor chip. The filling material may be reflective for the radiation emitted by the semiconductor chip. For example, the filling material is based on silicone or on epoxy. By way of example, the filling material covers the major part of the mounting area not already covered by the optoelectronic semiconductor chip(s).

According to at least one embodiment, a side surface of the semiconductor chip is wetted by the filling material. The side surface of the semiconductor chip is a surface running obliquely or perpendicularly to the mounting area of the carrier. Particularly, the side surface delimits the semiconductor chip in lateral direction, wherein lateral directions are herein defined as directions parallel to a main extension plane of the carrier and/or parallel to the mounting area.

The fact that the side surface is wetted by the filling material indicates that the filling material was applied to the mounting area in a liquid or viscous phase and that, due to minimization of surface energy, the liquid filling material has creeped onto the side surface. Particularly, the side surface of the semiconductor chip is wetted such that a surface of the filling material facing away from the side surface has a concave shape. That is, the thickness of the filling material on the side surface increases in direction towards the mounting area of the carrier. The side surface of the semiconductor chip may be partially or completely covered by the filling material. Several or all side surfaces of the semiconductor chip may be wetted by the filling material.

According to at least one embodiment, the optoelectronic device comprises at least one attraction feature at the mounting area laterally next to the semiconductor chip and laterally spaced from the semiconductor chip. The attraction feature is, preferably, also laterally spaced from the lateral ends or edges of the carrier. For example, at least the side surface of the semiconductor chip closest to the protrusion is wetted.

According to at least one embodiment, the attraction feature is at least laterally surrounded by the filling material. For example, the attraction feature is laterally completely surrounded by the filling material. In top view onto the mounting area of the carrier, a contiguous rail of the filling material may surround the attraction feature without interruptions. Particularly, the filling material may adjoin the attraction feature, e.g. on a side of the attraction feature facing the semiconductor chip and on the side of the attraction feature facing away from the semiconductor chip.

According to at least one embodiment, the attraction feature is different from the portion of mounting area laterally next to and surrounding the attraction feature. For example, the attraction feature differs from the mounting area laterally next to and surrounding the attraction feature in at least one physical property, like shape and/or material.

According to at least one embodiment, the attraction feature is configured such that it attracts a liquid phase of the filling material due to minimization of surface energy. As a consequence of this, a thickness of the filling material at the position of the attraction feature is greater than the thickness at this position if no attraction feature would have been used. Particularly, the attraction feature is configured to improve the coverage of the mounting area with the filling material, especially to improve the uniformity of the coverage in terms of the thickness.

The attraction due to minimization of the surface energy can be realized in different ways, e.g. by the shape of the attraction feature and/or the material of the attraction feature. The attraction feature may comprise or may be a protrusion and/or may comprise or consist of a material which results in a smaller contact angle of the liquid filling material than other regions of the mounting area around the attraction feature. Particularly, the attraction feature is configured such that, due to the attraction, it draws a portion of the filling material, which would creep on the side surface of the semiconductor chip if no attraction feature would be present, towards the attraction feature. Thus, with the attraction feature, the coverage of the side surface and/or the thickness on the side surface of the semiconductor chip is less than without the attraction feature.

The attraction feature is, in particular, a dummy feature or element of the optoelectronic device. For example, it has no other functionality than holding or attracting the filling material. Particularly, the attraction feature has no electrical functionality. During operation of the device, no electrical current flows through the attraction feature, for example.

In at least one embodiment, the optoelectronic device comprises a carrier with a mounting area, an optoelectronic semiconductor chip mounted at the mounting area of the carrier and a filling material arranged on the mounting area laterally next to the semiconductor chip, wherein a side surface of the semiconductor chip is wetted by the filling material. The optoelectronic device further comprises at least one attraction feature at the mounting area laterally next to and spaced from the semiconductor chip. The attraction feature is at least laterally surrounded by the filling material. The attraction feature is different from the portion of the mounting area which lies laterally next to the attraction feature and which laterally surrounds the attraction feature. Furthermore, the attraction feature is configured such that it attracts a liquid phase of the filling material due to minimization of surface energy.

The present invention is, inter alia, based on the recognition that, when dispensing a filling material, like a reflector silicone, around a semiconductor chip, said liquid filling material tends to creep onto the side surfaces of the semiconductor chip and, if applicable, on side surfaces of a housing wall of the optoelectronic device. This results in a low-volume, i.e. thin layer, of the filling material in the regions of the carrier distant from the semiconductor chip and the housing wall. A thin layer of the filling material is not desirable. For example in the case of the filling material being a reflector material, light can penetrate through the thin regions and can be absorbed by the carrier. This leads to poor brightness of the optoelectronic device.

The inventors of the present invention had the idea to introduce one or more attraction features in blank regions of the carrier, i.e. regions distant from the semiconductor chip and, if applicable, from the housing wall. With this design, in its liquid phase the filling material would creep and hold itself on the attraction feature(s). Hence, the amount of the filling material that creeps onto the semiconductor chip or onto the housing wall is reduced and, as a result, the thickness of the filling material on the carrier becomes more uniform.

According to at least one embodiment, the filling material extends continuously, e.g. without interruptions, from the wetted side surface of the semiconductor chip to the attraction feature.

According to at least one embodiment, the thickness of the filling material in the region laterally between the side surface of the semiconductor chip and the attraction feature is smaller than the height of the semiconductor chip. Heights and the thickness of the filling material on the mounting area are herein measured in a direction perpendicular to the main extension plane of the carrier and/or to the mounting area.

For example, the filling material is applied to the mounting area of the carrier with such a volume that the filling material does not project beyond the semiconductor chip in any region. The mounting area of the semiconductor chip facing away from the mounting area of the carrier is, in particular, free of the filling material.

According to at least one embodiment, the thickness of the filling material in a region laterally between the wetted side surface of the semiconductor chip and the attraction feature is smaller than the height to which said side surface of the semiconductor chip is wetted by the filling material.

For example, the thickness in said region laterally between the wetted side surface and the attraction feature is at most 80% or at most 60% of the height to which the side surface of the semiconductor chip is wetted. Additionally or alternatively, the thickness in said region laterally between the wetted side surface and the attraction feature is at least 20% or at least 30% or at least 50% of height to which the side surface of the semiconductor chip is wetted.

The surface of the filling material facing away from the mounting area in the region between the semiconductor chip and the attraction feature may be concavely shaped over a major part of its area or may be completely concavely shaped. “Major part” herein means more than 50%, e.g. at least 75%.

According to at least one embodiment, the attraction feature is a protrusion or comprises a protrusion protruding from the mounting area of the carrier in the same direction as the semiconductor chip. For example, the height of the protrusion, measured in the direction perpendicular to the mounting area and/or the main extension plane of the carrier, is at least 50 μm or at least 70 μm and/or at most 200 μm or at most 100 μm. The height of the protrusion is, for example, at most the height of the semiconductor chip, e.g. at most 75% or at most 50% of the height of the semiconductor chip. The protrusions may be cuboid. For example, the protrusion has an aspect ratio (height vs. maximal lateral extension) of larger than 1, for example at least 2. The protrusion may be pillar-shaped. Alternatively, the aspect ratio may be smaller than 1, e.g. at most 0.5 or at most 0.33 or at most 0.2. For example, a length of the protrusion is larger than its height. The protrusion may then be wall-shaped.

According to at least one embodiment, a side surface of the protrusion is wetted by the filling material. Also here, “wetted” means, in particular, that the filling material has creeped onto the side surface and that a surface of the filling material facing away from the side surface of the protrusion is concavely shaped. Side surfaces of the protrusion are surfaces of the protrusion delimiting the protrusion in lateral directions.

The wetted side surface of the protrusion may face the semiconductor chip and/or may be the side surface of the protrusion closest to the semiconductor chip. For example, several or all side surfaces of the protrusion are wetted by the filling material.

The height of the protrusion is, for example, greater than the thickness of the filling material in a region laterally between the protrusion and the semiconductor chip. A top side of the protrusion, facing away from the carrier is, for example, free of the filling material.

According to at least one embodiment, the thickness of the filling material in a region laterally between the wetted side surface of the semiconductor chip and the wetted side surface of the protrusion is smaller than the height to which said side surface of the protrusion is wetted by the filling material.

According to at least one embodiment, the protrusion has a convexly curved surface region. The convexly curved surface region is, for example, formed at an end of the protrusion most distant from the mounting area of the carrier. The convexly curved surface region may be a part of the side surface. For example, the convexly curved region is a region of the side surface adjoining the top side of the protrusion. The curvature radius of this region may be at least 1 μm or at least 10 μm and/or at most 100 μm or at most 50 μm. For example, the curvature radius is between 10% inclusive and 1000% inclusive of the height of the protrusion.

According to at least one embodiment, the convexly curved region is partially or completely wetted by the filling material. When the filling material creeps onto the convexly curved surface, an even more homogeneous thickness of the filling material on the mounting area can be obtained.

According to at least one embodiment, a housing wall laterally surrounds the semiconductor chip. For example, the housing wall laterally completely surrounds the semiconductor chip. That is, in top view onto the mounting area of the carrier, the housing wall forms a contiguous rail without interruptions around the semiconductor chip. The area of the carrier top side laterally surrounded by the housing wall is, in particular, the mounting area. The height of the housing wall is, for example, greater than the height of the semiconductor chip. The housing wall is, for example, laterally spaced from the semiconductor chip, e.g. by at least 100 μm or at least 200 μm or at least 800 μm.

The housing wall may be part of a housing body of the optoelectronic device. A portion of the housing body may form the carrier, e.g. together with the lead frame, and another portion of the housing body may form the housing wall. The housing body may be a molded body. For example, the housing body is formed in one piece.

According to at least one embodiment, a side surface of the housing wall facing the semiconductor chip and being laterally spaced from the semiconductor chip, is wetted by the filling material. Also here, “wetted” particularly means that the filling material has creeped onto the side surface and a surface of the filling material facing away from the side surface has a concave shape.

According to at least one embodiment, the attraction feature is arranged laterally spaced from the wetted side surface of the housing wall. For example, the attraction feature is arranged laterally between the semiconductor chip and the housing wall and is laterally spaced from both.

According to at least one embodiment, the filling material extends continuously from the wetted side surface of the housing wall to the attraction feature. The filling material may be formed contiguously over the entire mounting area.

According to at least one embodiment, the protrusion is made of the material of the housing wall. Particularly, the protrusion may be part of the housing body. For example, the protrusion is formed in one piece with the housing wall.

According to at least one embodiment, the mounting area is at least partially formed of the material of the housing wall. This portion of the mounting area may be formed by the housing body.

According to at least one embodiment, the protrusion is arranged at a portion of the mounting area formed of the material of the housing wall. Particularly, the attraction feature is arranged at the portion of the mounting area of the carrier formed by the material of the housing wall.

According to at least one embodiment, the filling material is reflective for the radiation emitted by the optoelectronic semiconductor chip, for example, the filling material is a silicone filled with reflective particles. The reflective particles may be TiO₂ particles.

According to at least one embodiment, the housing wall is made of an epoxy. Accordingly, the housing body may be formed of epoxy. The epoxy may be an epoxy mold compound.

According to at least one embodiment, the optoelectronic device comprises a plurality of attraction features. All features disclosed in connection with one attraction feature are also disclosed for all other attraction features.

According to at least one embodiment, the attraction features are arranged laterally around the semiconductor chip and are laterally spaced from each other pairwise. For example, each attraction feature is laterally spaced from the semiconductor chip or from every semiconductor chip and from the housing wall. Each attraction feature is furthermore laterally spaced from every other attraction feature.

Next, the mold for producing a molded body for an optoelectronic device is specified. The molded body is, for example, the housing body specified in connection with the here described optoelectronic device. Therefore, all features disclosed in connection with the optoelectronic device are also disclosed for the mold and vice versa.

In at least one embodiment, the mold is used for producing a molded body for an optoelectronic device, wherein the optoelectronic device has a carrier with a mounting area and an optoelectronic semiconductor chip mounted at the mounting area. At least a portion of the mounting area laterally adjacent to the semiconductor chip is formed by the molded body. The mold comprises a cavity to be filled with the mold material for the molded body. An inner surface of the mold delimiting the cavity defines said portion of the mounting area formed by the molded body. This inner surface comprises a recess to be filled with the mold material in order to produce a protrusion made of the mold material and protruding from said portion of the mounting area. The recess is spaced from lateral surfaces of the mold delimiting the cavity in lateral directions.

The mold may comprise a plurality of these recesses, each to be filled with the mold material in order to produce a protrusion. The produced protrusion(s) forms(form) the attraction feature(s) as specified above.

The lateral surfaces of the mold delimiting the cavity in lateral direction are surfaces running obliquely or perpendicularly to the inner surface of the mold, for example.

The molded body may be produced as follows: a carrier part, e.g. a lead frame, is arranged in the mold. An optoelectronic semiconductor chip may already be arranged on the carrier part. Then, a mold material is injected into the mold, wherein the lead frame is embedded into the mold material so that a carrier comprising the carrier part and the mold material is formed. At the mounting area of the carrier, the protrusion(s) resulting from the filling of the recess(es) is(are) formed. Afterwards, e.g. after curing the mold material, the carrier with the protrusions thereon is released from the mold. If the semiconductor chip was not already mounted on the carrier part, an optoelectronic semiconductor chip can now be mounted and, if applicable, electrically connected, to the carrier.

The mold may be configured such that a housing wall laterally surrounding the semiconductor chip is produced out of the mold material.

Next, the method for producing an optoelectronic device is specified. The method may, in particular, be used to produce an optoelectronic device as specified herein. Therefore, all features disclosed in connection with the optoelectronic device are also disclosed for the method and vice versa.

In at least one embodiment, the method for producing an optoelectronic device comprises a step of providing a carrier with an optoelectronic semiconductor chip mounted at a mounting area of the carrier and with at least one attraction feature at the mounting area laterally next to and spaced from the semiconductor chip. The attraction feature is different from the mounting area which laterally surrounds the attraction feature. In a further step, a liquid filling material is applied onto the mounting area of the carrier laterally next to the semiconductor chip and at least laterally around the attraction feature. Due to minimization of the surface energy, the liquid filling material wets the side surface of the semiconductor chip and is also attracted by the attraction feature. Afterwards, the filling material is cured.

In the case that the attraction feature is a protrusion, the liquid filling material creeps onto side surface(s) of the protrusion, for example.

The attraction by the side surface of the semiconductor chip and by the attraction feature results in a homogeneous thickness of the filling material across the mounting area, at least in a more homogeneous thickness than in the case that no attraction feature is used.

According to at least one embodiment, the volume of the liquid filling material applied onto the mounting area is chosen such that the thickness of the filling material stays below the height of the semiconductor chip. Particularly, the filling material is applied such that the top side of the semiconductor chip facing away from the mounting area of the carrier stays free of the filling material.

According to at least one embodiment, providing the carrier comprises producing a molded body using the mold described herein and filling the cavity with a mold material.

According to at least one embodiment, the molded body is produced using transfer molding.

### BRIEF DESCRIPTION OF THE DRAWINGS

Hereinafter, the optoelectronic device, the mold for producing a molded body for an optoelectronic device and the method for producing an optoelectronic device will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures. For the sake of clarity, elements might not appear with corresponding reference symbols in all figures.

FIG. 1 shows an example of an optoelectronic device in a cross-sectional view;

FIG. 2 shows a first exemplary embodiment of the optoelectronic device in cross-sectional view;

FIG. 3 shows a position in an exemplary embodiment of the method for producing an optoelectronic device;

FIG. 4 shows a further exemplary embodiment of the optoelectronic device;

FIGS. 5 and 6 show cross-sectional views of the exemplary embodiment of FIG. 4;

FIG. 7 shows a position in a further exemplary embodiment of the method for producing an optoelectronic device;

FIG. 8 shows a further exemplary embodiment of the optoelectronic device;

FIGS. 9 and 10 show sections of an exemplary embodiment of the optoelectronic device;

FIG. 11 shows an exemplary embodiment of the mold for producing a molded body and a first position of an exemplary embodiment of the method for producing an optoelectronic device; and

FIGS. 12 and 13 show further positions in an exemplary embodiment of the method for producing an optoelectronic device.

### DETAILED DESCRIPTION OF ILLUSTRATIVE EMBODIMENTS

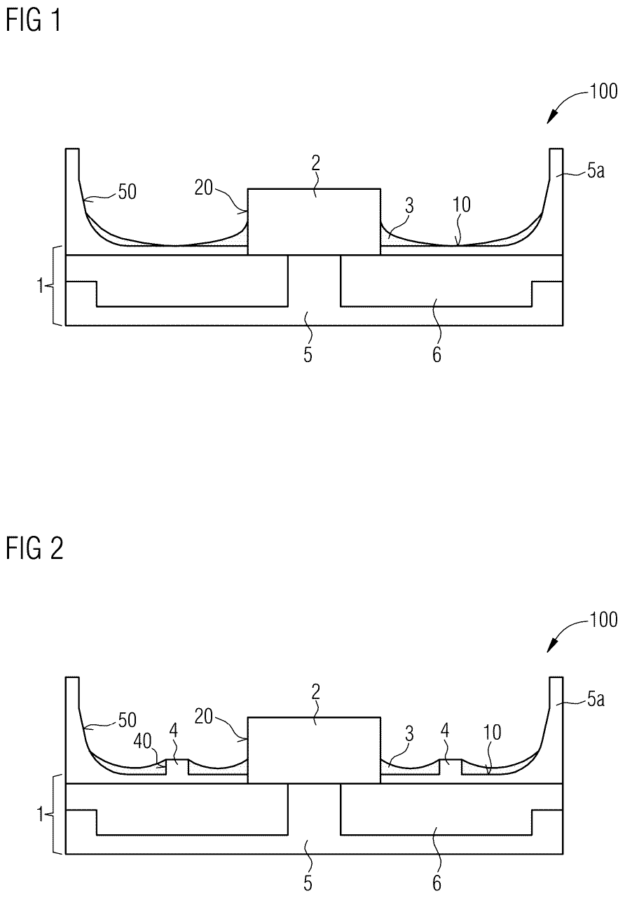

FIG. 1 shows an optoelectronic device 100 in a cross-sectional view. The optoelectronic device 100 comprises a housing body 5 in the form of a molded body 5. The housing body 5 is, for example, formed of epoxy. A lead frame 6 is embedded in the housing body 5. The lead frame 6 and the housing body 5 together form a carrier 1 with a mounting area 10, at which an optoelectronic semiconductor chip 2 is mounted. A portion of the housing body 5 forms a housing wall 5a which laterally surrounds the semiconductor chip 2 and which projects beyond the semiconductor chip 2 in the direction perpendicular to the mounting area 10 of the carrier 1.

The optoelectronic semiconductor chip 2 is, for example, configured to emit electromagnetic radiation during operation. The semiconductor chip 2 is a flip-chip. For example, the semiconductor chip 2 is based on AlGaInN.

During operation, a part of the radiation emitted by the semiconductor chip 2 is emitted towards the mounting area 10 of the carrier 1. This bears the risk that this part of the radiation is absorbed by the carrier 1. In order to prevent this, a reflective filling material 3 is applied onto the mounting area 10 of the carrier 1 in regions laterally next to the semiconductor chip 2. The filling material 3 is, for example, based on silicone filled with reflective particles, like TiO₂ particles. The volume of the filling material 3 filled into the cavity surrounded by the housing wall 5a is chosen such that the thickness of the filling material 3 stays below the height of the semiconductor chip 2 and below the height of the housing wall 5a in order to avoid, for example, a covering of the top side of the semiconductor chip 2 by the filling material 3.

Since the filling material 3 has been applied in a liquid or viscous phase, respectively, it has minimized its surface energy by creeping onto the side surfaces 20 of the semiconductor chip 2 and also onto the side surfaces 50 of the housing wall 5a and has thereby wetted these surfaces 20, 50. Due to the chosen filling volume of the filling material 3, the surfaces of the filling material 3 facing away from the wetted surfaces 20, 50 have a concave shape. Moreover, the thickness of the filling material 3 in a region laterally between the semiconductor chip 2 and the housing wall 5a has become very small as a consequence of the creepage onto the side surfaces 20, 50. In this region of very small thickness, radiation from the semiconductor chip 2 may pass through the filling material 3 and may be absorbed by the carrier 1.

FIG. 2 shows an exemplary embodiment of the optoelectronic device 100 which is very similar to the optoelectronic device 100 of FIG. 1, but in which the problem of the very thin filling material 3 in the region laterally between the semiconductor chip 2 and the housing wall 5a is avoided by the introduction of attraction features 4 at the mounting area 10 of the carrier 1. Here, the attraction features 4 are protrusions made of the material of the housing body 5 and protruding from the mounting area 10 in the same direction as the semiconductor chip 2. The protrusions 4 are arranged laterally spaced from the semiconductor chip 2 and from the housing wall 5a. The protrusions 4 attract the liquid filling material 3 during production of the optoelectronic device 100 due to minimization of the surface energy of the liquid filling material 3. Specifically, the filling material 3 creeps onto the lateral surfaces 40 of the protrusions 4. Thereby a portion of the filling material 3, which would have creeped onto the sides surfaces 20, 50 of the semiconductor chip 2 and the housing wall 5a, is drawn away from the semiconductor chip 2 or the housing wall 5a, respectively. As a consequence, the thickness of the filling material in the region laterally between the semiconductor chip 2 and the housing wall 5a becomes more homogenous than compared to FIG. 1. With this, the risk of a part of the radiation emitted by the semiconductor chip 2 passing through the filling material 3 is reduced and the overall brightness of the optoelectronic device 100 is increased.

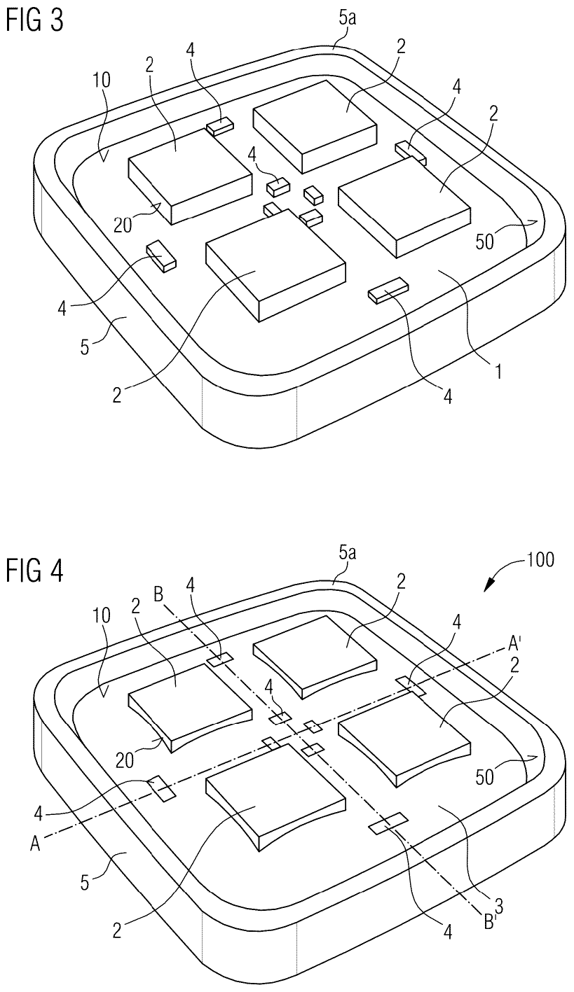

FIG. 3 shows a position in an exemplary embodiment of the method for producing an optoelectronic device 100. In this position, a carrier 1 with a mounting area 10 and four optoelectronic semiconductor chips 2 mounted on the mounting area 10 are provided. Also here, the semiconductor chips 2 are surrounded by a housing wall 5a of a housing body 5. A plurality of attraction features 4, each the in form of a protrusion 4, are arranged on the mounting area 10. In each case the protrusions 4 are laterally spaced from the semiconductor chips 2, the housing wall 5a and are also spaced from each other.

FIG. 4 shows an exemplary embodiment of the optoelectronic device 100 in a perspective view. This optoelectronic device 100 is, for example, produced by filling a liquid filling material 3 in the cavity surrounded by the housing wall 5a and onto the mounting area 10 of FIG. 3. As can be seen, the filling material 3 has creeped onto the side surfaces 20 of the semiconductor chips 2 and the sides surface 50 of the housing wall 5a. However, the filling material 3 has also creeped onto the side surfaces of the protrusions 4 and, as a consequence, a more homogeneous thickness of the filling material 3 across the mounting area 10 is obtained as compared to the case without the protrusions 4.

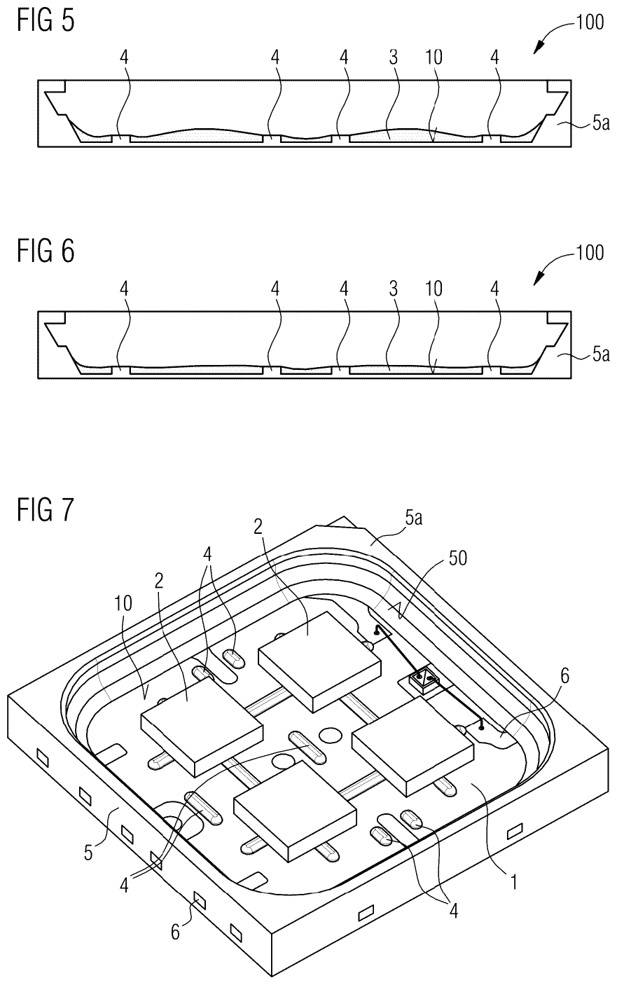

FIGS. 5 and 6 show cross-sectional views along the cutting lines AA′ and BB′ of FIG. 4. As can be seen here, the thickness of the filling material 3 is indeed rather homogeneous. Particularly, there are no regions in which the thickness of the filling material 3 is so low that radiation emitted by the semiconductor chips 2 could pass through the filling material 3 towards the carrier.

FIG. 7 shows a position in a further exemplary embodiment of the method for producing an optoelectronic device 100. This position is similar to the position of FIG. 3, in which a carrier 1 with a mounting area 10 and a plurality of optoelectronic semiconductor chips 2 mounted at the mounting area 10 is provided. The carrier 10 and the semiconductor chips 2 are laterally surrounded by a housing wall 5a of a housing body 5 which also forms part of the carrier 1. Also here, a plurality of attraction features 4 in the form of protrusions 4 is arranged at the mounting area 10. In each case the protrusions 4 are wall-shaped.

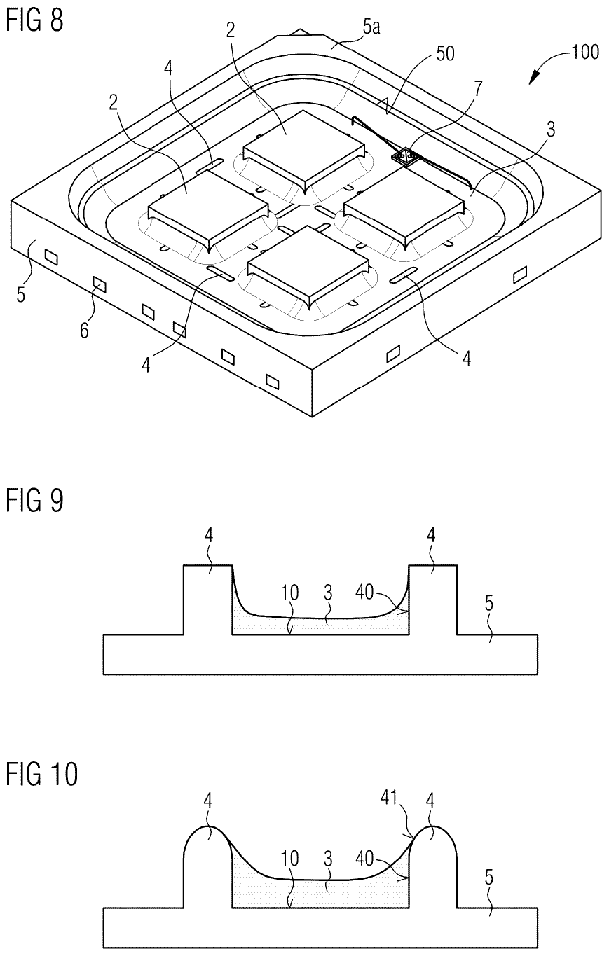

FIG. 8 shows a further exemplary embodiment of the optoelectronic device 100 which is, for example, produced by applying a liquid filling material 3 onto the mounting area 10 of the carrier 1 of FIG. 7. The liquid filling material 3 has creeped onto the side surface 50 of the housing wall 5a and the side surfaces 20 of the semiconductor chips 2. However, as the liquid filling material 3 has also creeped onto the side surfaces of the protrusions 4, a rather homogeneous thickness of the filling material 3 across the mounting area 10 of the carrier is obtained.

FIGS. 9 and 10 show sections of two exemplary embodiments of the optoelectronic device 100. In FIG. 9, the protrusions 4 have sharp edges between their top sides facing away from the carrier 1 and their side surfaces 40. In FIG. 10, a region 41 of the surface of the protrusions 4 is convexly shaped. In FIG. 9 and FIG. 10, the contact angle of the filling material is 20°. As becomes clear from FIGS. 9 and 10, as a consequence of the convex shape of the surface region 41, the thickness of the filling material 3 is even more homogeneous.

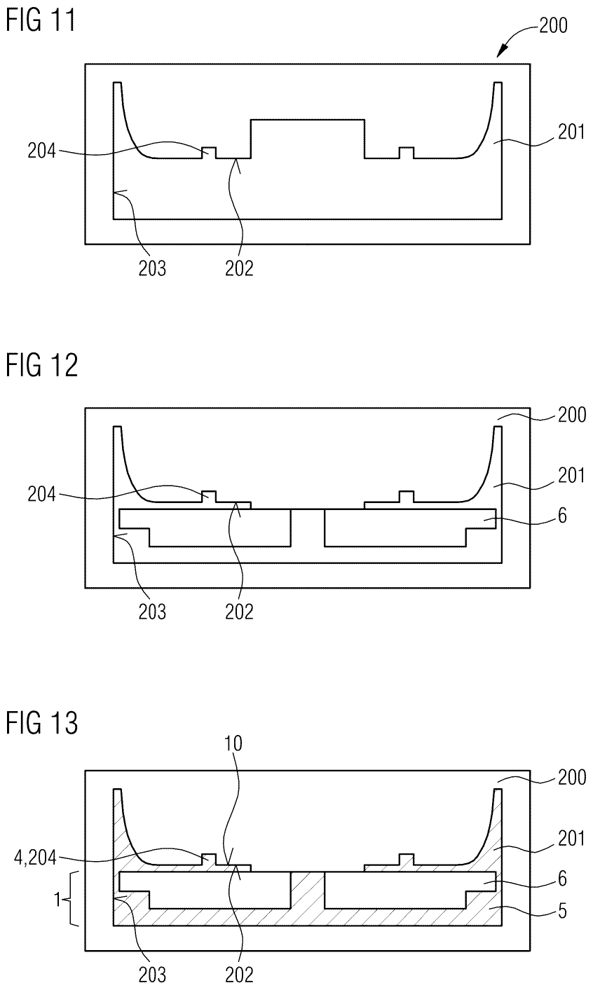

FIG. 11 shows an exemplary embodiment of a mold 200 for producing a molded body for an optoelectronic device. The mold 200 comprises a cavity 201 to be filled with a mold material. The cavity 201 has an essentially complementary shape to the shape of the carrier 1 together with the housing wall 5a of FIGS. 1 and 2. An inner surface 202 of the mold 200 delimits the cavity and defines a portion of the to be produced mounting area 10 of the carrier 1. This inner surface 202 comprises a recess 204 which is foreseen to be filled with the mold material in order to produce a protrusion made of the mold material. This protrusion will then protrude from mounting area 10. The recesses 204 are spaced from lateral surfaces 203 of the mold 200, said lateral surfaces 203 delimiting the cavity 201 in lateral directions.

FIG. 12 shows a position in an exemplary embodiment of the method for producing an optoelectronic device. In this position, a lead frame 6 is arranged in the cavity 201 of the mold 200.

In the position of FIG. 13, the cavity 201 is filled with the mold material 5. The mold material 5 surrounds the lead frame 6, whereby a carrier 1 is formed. The mold material 5 also fills the recesses 204 so that protrusions 4 are formed laterally next to the position where the semiconductor chip 2 is to be mounted. The protrusions 4 project from the mounting area 10 of the carrier 1.

After this step, the mold material 5 is cured so that a molded body 5 or housing body 5, respectively, is formed. The molded body 5, together with the lead frame 6 embedded therein, can then be released from the mold 200. An optoelectronic semiconductor chip 2 may then be mounted on the mounting area 10. The optoelectronic semiconductor device 100 is, for example, finalized by applying the filling material 3 onto the mounting area 10 of the carrier 1 as described before.

The invention described herein is not limited by the description in conjunction with the exemplary embodiments. Rather, the invention comprises any new feature as well as any combination of features, particularly including any combination of features in the patent claims, even if said feature or said combination per se is not explicitly stated in the patent claims or exemplary embodiments.

1.-15. (canceled)

16. An optoelectronic device comprising:
a carrier with a mounting area;
an optoelectronic semiconductor chip mounted at the mounting area of the carrier;
a filling material arranged on the mounting area laterally next to the semiconductor chip, wherein a side surface of the semiconductor chip is wetted by the filling material;
at least one attraction feature at the mounting area laterally next to and spaced from the semiconductor chip, wherein the attraction feature is at least laterally surrounded by the filling material, is different from a portion of the mounting area laterally next to and surrounding the attraction feature, is configured to attract a liquid phase of the filling material due to a minimization of surface energy, and is a protrusion protruding from the mounting area of the carrier in the same direction as the semiconductor chip,
wherein a side surface of the protrusion is wetted by the filling material,
wherein the protrusion has a convexly curved surface region facing away from the mounting area of the carrier and is wetted at least partially with the filling material, and
wherein a curvature radius of the convexly curved surface region is between 10% inclusive and 1000% inclusive of a height of the protrusion.

17. The optoelectronic device according to claim 16,
wherein the filling material extends continuously from the wetted side surface of the semiconductor chip to the attraction feature,
wherein a thickness of the filling material in a region laterally between the wetted side surface of the semiconductor chip and the attraction feature is smaller than a height of semiconductor chip, and
wherein the thickness of the filling material in a region laterally between the wetted side surface of the semiconductor chip and the attraction feature is smaller than a height to which the side surface of the semiconductor chip is wetted by the filling material.

18. The optoelectronic device according to claim 16, wherein a thickness of the filling material in a region laterally between the wetted side surface of the semiconductor chip and the wetted side surface of the protrusion is smaller than a height to which said side surface of the protrusion is wetted by the filling material.

19. The optoelectronic device according to claim 16, further comprising:
a housing wall laterally surrounding the semiconductor chip,
wherein a side surface of the housing wall facing the semiconductor chip and being laterally spaced from the semiconductor chip is wetted by the filling material,
wherein the attraction feature is arranged laterally spaced from the wetted side surface of the housing wall, and
wherein the filling material extends continuously from the wetted side surface of the housing wall to the attraction feature.

20. The optoelectronic device according to claim 19, wherein the protrusion is made of the material of the housing wall.

21. The optoelectronic device according to claim 19,
wherein the mounting area is at least partially formed of the material of the housing wall, and
wherein the protrusion is arranged at the portion of the mounting area formed of the material of the housing wall.

22. The optoelectronic device according to claim 19,
wherein the filling material is a silicone filled with reflective particles, and
wherein the housing wall is made of an epoxy.

23. The optoelectronic device according to claim 16, further comprising:
a plurality of attraction features,
wherein the attraction features are arranged laterally around the semiconductor chip and are laterally spaced from each other pairwise.

24. A mold for producing a molded body for an optoelectronic device, wherein the optoelectronic device has a carrier with a mounting area and an optoelectronic semiconductor chip mounted at the mounting area, and wherein at least a portion of the mounting area laterally adjacent to the semiconductor chip is formed by the molded body, the mold comprising:
a cavity to be filled with a mold material for the molded body; and
an inner surface of the mold delimiting the cavity,
wherein the inner surface, defining the portion of the mounting area, comprises a recess to be filled with the mold material in order to produce a protrusion made of the mold material and protruding from the portion of the mounting area, and
wherein the recess is spaced from lateral surfaces of the mold delimiting the cavity in lateral directions.

25. A method for producing an optoelectronic device, the method comprising:
providing a carrier with an optoelectronic semiconductor chip mounted at a mounting area of the carrier and at least one attraction feature at the mounting area laterally next to and spaced from the semiconductor chip,
wherein the attraction feature is different from the mounting area, which laterally surrounds the attraction feature, is a protrusion protruding from the mounting area of the carrier in the same direction as the semiconductor chip, wherein the protrusion has a convexly curved surface region facing away from the mounting area of the carrier, and wherein a curvature radius of the convexly curved surface region is between 10% inclusive and 1000% inclusive of a height of the protrusion;
applying a liquid filling material onto the mounting area of the carrier laterally next to the semiconductor chip and at least laterally around the attraction feature, wherein, due to minimization of surface energy, the liquid filling material creeps onto a side surface of the semiconductor chip and is attracted by the attraction feature; and
curing the liquid filling material.

26. The method according to claim 25, wherein a volume of the liquid filling material applied onto the mounting area is chosen such that a thickness of the liquid filling material stays below a height of the semiconductor chip.

27. The method according to claim 25, wherein providing the carrier comprises producing a molded body using a mold and filling a cavity with a mold material.

28. The method according to claim 27, wherein the molded body is produced using transfer molding.
